(19) United States
(12) Patent Application Publication
(10) Pub. No.: US 2023/0282456 A1
(43) Pub. Date: Sep. 7, 2023

(54) PLASMA PROCESSING APPARATUS

(71) Applicant: KIOXIA CORPORATION, Tokyo (JP)

(72) Inventor: Tomohiro TAMURA, Mie Mie (JP)

(73) Assignee: KIOXIA CORPORATION, Tokyo (JP)

(21) Appl. No.: 17/898,853

(22) Filed: Aug. 30, 2022

(30) Foreign Application Priority Data
Mar. 2, 2022 (JP) 2022-031647

(51) Int. Cl. H01J 37/32

(52) U.S. Cl. CPC H01J 37/32715; H01J 37/32568; H01J 2237/2007; H01J 2237/334; H01J 2237/20278; H01J 2237/20235

(57) ABSTRACT

According to one embodiment, a plasma processing apparatus generates plasma between a lower electrode and an upper electrode. The plasma processing apparatus includes a processing table, a central top plate, an outer peripheral top plate, and a driver. The processing table is electrically connected to the lower electrode and includes a mounting surface on which a substrate to be treated is mounted. The central top plate is electrically connected to the upper electrode and includes a central surface facing the mounting surface. The outer peripheral top plate is electrically connected to the upper electrode and includes an outer peripheral surface facing the mounting surface and surrounds the outer periphery of the central surface. The driver relatively displaces the central top plate and the outer peripheral top plate.

### CROSS-REFERENCE TO RELATED APPLICATION

This application is based upon and claims the benefit of priority from Japanese Patent Application No. 2022-031647, filed Mar. 2, 2022, the entire contents of which are incorporated herein by reference.

### FIELD

Embodiments described herein relate generally to a plasma processing apparatus.

### BACKGROUND

In the manufacturing process of semiconductor devices, plasma processing apparatuses that perform surface treatment of substrates using plasma generated between a pair of electrodes are used. Such a plasma processing apparatus is used, for example, to form a pattern in a central portion of a substrate or to perform bevel processing on an outer edge portion of the substrate. However, in the structure of the related art, it is difficult to perform the treatment on the central portion and the treatment on the outer edge portion of the substrate with the same plasma processing apparatus.

### DESCRIPTION OF THE DRAWINGS

FIG. 1 is a cross-sectional view showing an example of a configuration of a plasma processing apparatus of an embodiment;

FIG. 2 is a bottom view showing an example of a configuration of a central top plate and an outer peripheral top plate of the embodiment;

FIG. 3 is a cross-sectional view showing an example of a state of the plasma processing apparatus of the embodiment when performing the treatment on the outer edge portion of the substrate; and

FIG. 4 is a cross-sectional view showing an example of a state of the plasma processing apparatus of the embodiment when performing the treatment on the central portion of the substrate.

### DETAILED DESCRIPTION

Embodiments provide a plasma processing apparatus capable of performing the treatment on a central portion of a substrate and the treatment on an outer edge portion with the same apparatus.

In general, according to one embodiment, the plasma processing apparatus generates plasma between a lower electrode and an upper electrode. The plasma processing apparatus includes a processing table, a central top plate, an outer peripheral top plate, and a drive mechanism or driver. The processing table is electrically connected to the lower electrode and includes a mounting surface on which a substrate to be treated is mounted. The central top plate is electrically connected to the upper electrode and includes a central surface facing the mounting surface. The outer peripheral top plate is electrically connected to the upper electrode and includes an outer peripheral surface faced the mounting surface and surrounds the outer periphery of the central surface. The drive mechanism relatively displaces the central top plate and the outer peripheral top plate.

The plasma processing apparatus according to the embodiment will be described below with reference to the attached drawings. The present disclosure is not limited to the following embodiments. Further, the components in the following embodiments include those that can be easily assumed by those skilled in the art or those that are substantially the same.

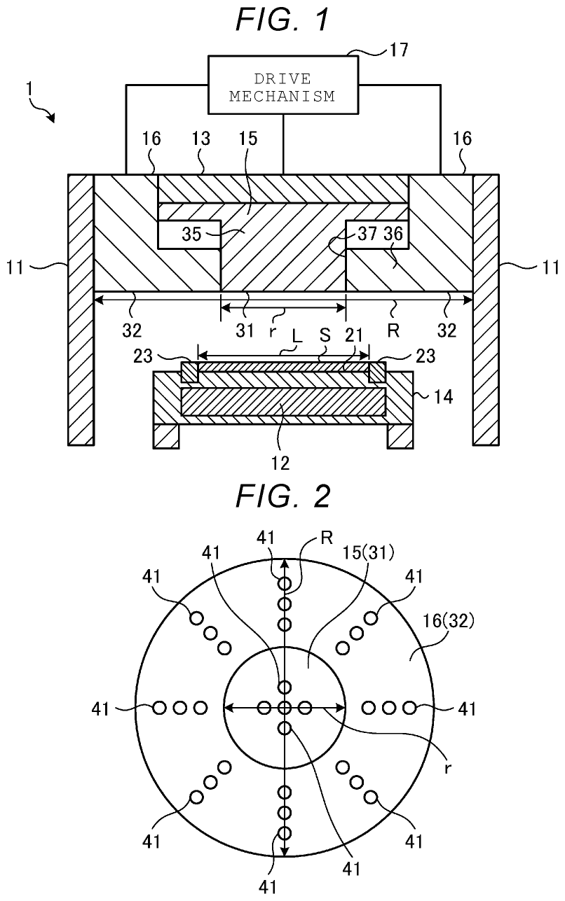

FIG. 1 is a cross-sectional view showing an example of the configuration of a plasma processing apparatus 1 of the embodiment. The plasma processing apparatus 1 includes a chamber 11, a lower electrode 12, an upper electrode 13, a processing table 14, a central top plate 15, an outer peripheral top plate 16, and a drive mechanism or driver 17. The plasma processing apparatus 1 of the present embodiment is a capacitive coupling type plasma processing apparatus that can perform a predetermined surface treatment to a substrate S by generating plasma in a processing space formed between a pair of electrodes (lower electrode 12 and upper electrode 13).

The chamber 11 is a cylindrical structure, and a processing space for generating plasma is formed in the chamber 11. The upper part of the chamber 11 is sealed with the central top plate 15, the outer peripheral top plate 16, and an appropriate sealing material. The bottom portion of the chamber 11 is provided with a mechanism capable of discharging the gas in the processing space.

The lower electrode 12 is located at the lower part in the chamber 11 and is connected to a power supply device that outputs a high-frequency voltage. The power supply device may be configured with, for example, an AC power supply, a frequency regulator, an amplifier, an impedance matching device, or the like. The upper electrode 13 is located at the upper part in the chamber 11 and is grounded. The upper electrode 13 may be connected to the power supply device, and the lower electrode 12 may be grounded.

The processing table 14 is a structure that supports the substrate S to be treated, is made of a conductive material, and is electrically connected to the lower electrode 12. The processing table 14 includes a mounting surface 21 on which the substrate S is mounted, and a fixing member 23 for fixing the substrate S mounted on the mounting surface 21.

The central top plate 15 and the outer peripheral top plate 16 are made of a conductive material and are electrically connected to the upper electrode 13. Further, the central top plate 15 and the outer peripheral top plate 16 are each configured with independent members and can be relatively displaced by the action of the drive mechanism 17. The central top plate 15 includes a central surface 31 facing the mounting surface 21 of the processing table 14. The outer peripheral top plate 16 includes an outer peripheral surface 32 facing the mounting surface 21, and the outer peripheral surface 32 surrounds the outer periphery of the central surface 31 of the central top plate 15.

The central top plate 15 of the present embodiment has a protruding cross-sectional shape in the vertical direction, and the lower surface of the protruding portion 35 protruding downward is the central surface 31. The outer peripheral top plate 16 of the present embodiment has a recessed cross-sectional shape in the vertical direction, and the lower surface of the bottom portion 36 is the outer peripheral surface 32. An opening 37 penetrating in the vertical direction is formed in the central portion of the bottom portion 36. The protruding portion 35 of the central top plate 15 is slidably inserted into the opening 37 of the outer peripheral top plate 16. With such a structure, the central top plate 15 and the outer peripheral top plate 16 can be relatively displaced in the vertical direction. The structures of the central top plate 15 and the outer peripheral top plate 16 are not limited to the above. Further, in the present embodiment, the upper electrode 13, the central top plate 15, and the outer peripheral top plate 16 are each configured with individual members. However, for example, the upper electrode 13 and the central top plate 15 may be configured with the same member, and the upper electrode 13 and the outer peripheral top plate 16 may be configured with the same member.

FIG. 2 is a bottom view showing an example of the configuration of the central top plate 15 and the outer peripheral top plate 16 of the embodiment. As shown in FIG. 2, a plurality of ejection holes 41 for ejecting a processing gas (for example, CF₄ or the like) used for a predetermined surface treatment (for example, dry etching or the like) is provided on the central surface 31 of the central top plate 15 and the outer peripheral surface 32 of the outer peripheral top plate 16 of the present embodiment. In FIG. 1, the description of the ejection hole 41 is omitted. The formation positions, number, shape, and the like of the ejection holes 41 shown in FIG. 2 are merely examples, and the embodiments of the ejection holes 41 are not limited thereto. Further, the mechanism that ejects the processing gas may be provided, for example, on the wall surface of the chamber 11.

Here, when the diameter of the central surface 31 is r, the outer diameter of the outer peripheral surface 32 is R, and the diameter of the substrate S to be treated is L, the following formula (1) is established. As a result, the central surface 31 can be used to perform the treatment on the central portion of the substrate S, and the outer peripheral surface 32 can be used to perform the treatment on the outer edge portion of the substrate S.

r<L<R (1)

Further, in addition to the above formula (1), it is preferable that the following formula (2) is established. For example, when the substrate S to be treated is a disk-shaped substrate having a diameter of 300 mm, the diameter r of the central surface 31 is preferably 150 mm or more. By designing so that the area of the central surface 31 is increased to some extent in this way, it is possible to improve the workability of the treatment on the outer edge portion of the substrate S.

r>L/2 (2)

The drive mechanism 17 is a mechanism that relatively displaces the central top plate 15 and the outer peripheral top plate 16 in the vertical direction. The specific configuration of the drive mechanism 17 is not particularly limited and may be configured with an appropriate mechanism such as a motor, an actuator, an electronic control device, or the like. Further, the drive mechanism 17 may further displace the processing table 14 (mounting surface 21) in the vertical direction.

In the plasma processing apparatus 1 having the above configuration, when a high-frequency voltage is applied to the lower electrode 12 (or the upper electrode 13) with the chamber 11 filled with the processing gas, plasma is generated between the upper surface of the substrate S mounted on the mounting surface 21, and the central surface 31 or the outer peripheral surface 32. At this time, when the distance between the mounting surface 21 (upper surface of the substrate S) and the central surface 31 or the outer peripheral surface 32 becomes smaller than a predetermined threshold value, plasma is not generated.

The drive mechanism 17 of the present embodiment utilizes the above phenomenon to adjust the distance (first distance) between the mounting surface 21 and the central surface 31, and the distance (second distance) between the mounting surface 21 and the outer peripheral surface 32, depending on which part of the substrate S is to be treated.

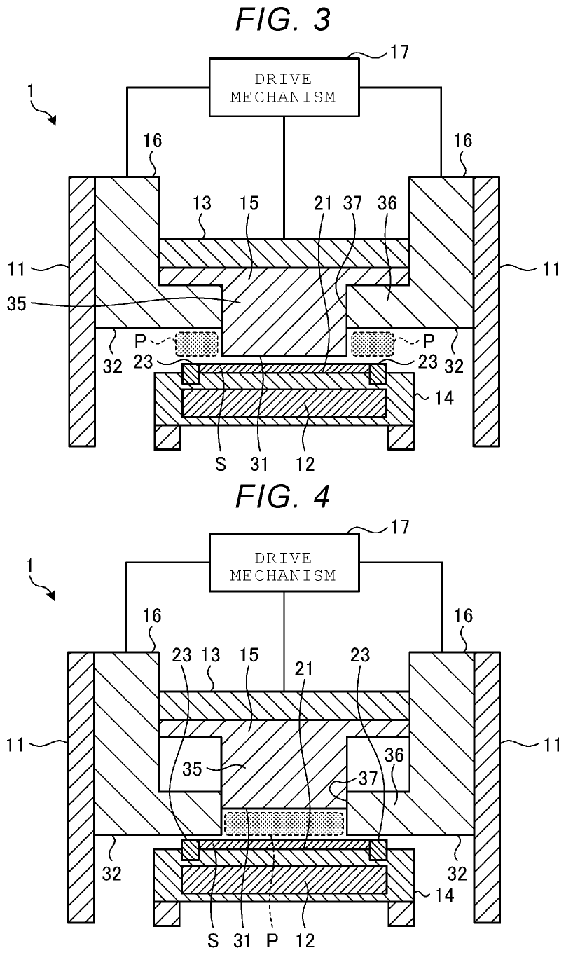

FIG. 3 is a cross-sectional view showing an example of a state of the plasma processing apparatus 1 of the embodiment when performing the treatment on the outer edge portion of the substrate S. As shown in FIG. 3, when performing the treatment on the outer edge portion of the substrate S, the drive mechanism 17 displaces at least one of the central top plate 15 and the outer peripheral top plate 16 so that the distance (first distance) between the mounting surface 21 and the central surface 31 is smaller than the threshold value and the distance (second distance) between the mounting surface 21 and the outer peripheral surface 32 becomes equal to or larger than the threshold value. At this time, the processing table 14 may be displaced. As a result, a plasma region P can be formed only on the outer edge portion of the substrate S, and a predetermined treatment (for example, bevel processing or the like) can be applied only to the outer edge portion of the substrate S.

FIG. 4 is a cross-sectional view showing an example of a state of the plasma processing apparatus 1 of the embodiment when performing the treatment on the central portion of the substrate S. As shown in FIG. 4, when performing the treatment on the central portion of the substrate S, the drive mechanism 17 displaces at least one of the central top plate 15 and the outer peripheral top plate 16 so that the distance (first distance) between the mounting surface 21 and the central surface 31 is equal to or larger than the threshold value, and the distance (second distance) between the mounting surface 21 and the outer peripheral surface 32 is smaller than the threshold value. At this time, the processing table 14 may be displaced. As a result, the plasma region P can be formed only in the central portion of the substrate S, and a predetermined treatment (for example, pattern formation or the like) can be applied only to the central portion of the substrate S.

As described above, according to the present embodiment, it is possible to execute the treatment on the central portion of the substrate S and the treatment on the outer edge portion of the substrate S with the same plasma processing apparatus 1.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A plasma processing apparatus that generates plasma between a lower electrode and an upper electrode, the apparatus comprising:
a processing table that is electrically connected to the lower electrode and includes a mounting surface on which a substrate to be treated is mounted;
a central top plate that is electrically connected to the upper electrode and includes a central surface facing the mounting surface;
an outer peripheral top plate that is electrically connected to the upper electrode and includes an outer peripheral surface facing the mounting surface and surrounds an outer periphery of the central surface; and
a driver that relatively displaces the central top plate and the outer peripheral top plate.

2. The plasma processing apparatus according to claim 1, wherein
when performing a treatment on an outer edge portion of the substrate, the driver displaces at least one of the central top plate or the outer peripheral top plate such that a first distance between the mounting surface and the central surface becomes smaller than a threshold value, and a second distance between the mounting surface and the outer peripheral surface is equal to or larger than the threshold value.

3. The plasma processing apparatus according to claim 1, wherein
when performing a treatment on a central region in an outer edge portion of the substrate, the driver displaces at least one of the central top plate or the outer peripheral top plate such that a first distance between the mounting surface and the central surface becomes equal to or larger than a threshold value, and a second distance between the mounting surface and the outer peripheral surface becomes smaller than the threshold value.

4. The plasma processing apparatus according to claim 1, wherein
when a diameter of the central surface is r, an outer diameter of the outer peripheral surface is R, and a diameter of the substrate is L, the following formula (1) is established:
r<L<R (1).

5. The plasma processing apparatus according to claim 4, wherein the central surface is used to perform a treatment on a central portion of the substrate.

6. The plasma processing apparatus according to claim 4, wherein the outer peripheral surface is used to perform a treatment on an outer edge portion of the substrate.

7. The plasma processing apparatus according to claim 4, wherein
the following formula (2) is further established:
r>L/2 (2).

8. The plasma processing apparatus according to claim 1, wherein
the central top plate has a protruding portion protruding downward in a vertical direction,
the central surface is formed on a lower surface of the protruding portion,

9. The plasma processing apparatus according to claim 8, wherein
the outer peripheral top plate includes a bottom surface having an opening penetrating in the vertical direction,
the outer peripheral surface is formed on a lower surface of the bottom surface, and
the protruding portion is slidably inserted into the opening.

10. The plasma processing apparatus according to claim 9, wherein
the central top plate and the outer peripheral top plate are relatively displaced in the vertical direction

11. The plasma processing apparatus according to claim 1, wherein the driver further displaces the processing table.

12. The plasma processing apparatus according to claim 11, wherein the driver further displaces the processing table in the vertical direction.

13. The plasma processing apparatus according to claim 1, wherein the driver includes at least one of a motor, an actuator, or an electronic control device.

14. The plasma processing apparatus according to claim 1, wherein
an ejection hole for ejecting gas is formed on at least one of the central surface or the outer peripheral surface.

15. The plasma processing apparatus according to claim 14, wherein
the ejection hole includes a plurality of ejection holes for ejecting a processing gas.

16. The plasma processing apparatus according to claim 1, wherein
the processing table further includes a fixing member for fixing the substrate mounted on the mounting surface.
